(19) United States
(12) Patent Application Publication
(10) Pub. No.: US 2021/0398824 A1
(43) Pub. Date: Dec. 23, 2021

(54) BATCH WAFER DEGAS CHAMBER AND INTEGRATION INTO FACTORY INTERFACE AND VACUUM-BASED MAINFRAME

(71) Applicant: Applied Materials, Inc., Santa Clara, CA (US)

(72) Inventors: Dean C. Hruzek, Cedar Park, TX (US); Nir Merry, Mountain View, CA (US); Marek Radko, San Jose, CA (US); Paul B. Reuter, Austin, TX (US); Steven Sansoni, Livermore, CA (US); Sushant S. Koshti, Sunnyvale, CA (US); John Joseph Mazzocco, San Jose, CA (US); Juan Chacin, Kailua-Kona, HI (US)

(21) Appl. No.: 16/946,407

(22) Filed: Jun. 19, 2020

(51) Int. Cl. H01L 21/67; H01L 21/677

(52) U.S. Cl. CPC H01L 21/67017; H01L 21/67098; H01L 21/67739; H01L 21/6719

(57) ABSTRACT

A substrate processing system includes an equipment front end module (EFEM) coupled to a vacuum-based mainframe, the EFEM including multiple interface openings. The system further includes a batch degas chamber attached to the EFEM at an interface opening of the multiple interface openings. The batch degas chamber includes a housing that is sealed to the interface opening of the EFEM. Within the housing is located a cassette configured to hold multiple substrates. A reactor chamber, attached to the housing, is to receive the cassette and perform an active degas process on the multiple substrates. The active degas process removes moisture and contaminants from surfaces of the multiple substrates. An exhaust line is attached to the reactor chamber to provide an exit for the moisture and contaminants.

### TECHNICAL FIELD

The present application relates to electronic device manufacturing, and more specifically to batch wafer degas chambers of equipment front end modules (EFEMs), and integration thereof into a vacuum-based mainframe.

### BACKGROUND

Processing of substrates in semiconductor component manufacturing is carried out in multiple process tools, where the substrates travel between the process tools in substrate carriers (e.g., Front Opening Unified Pods or FOUPs). The FOUPs may be docked to a front wall of an EFEM that includes a load/unload robot that is operable to transfer substrates between the respective FOUPs and one or more destinations (e.g., load lock(s) or processing chamber(s)) coupled to a rear wall of the EFEM opposite the front wall. A substrate processing system, e.g., to include a vacuum-based mainframe to which these multiple process tools are attached, endeavors to have lower levels of contamination, higher levels of vacuum, and better productivity in order to meet tolerances and high yields for many deposition processes.

### SUMMARY

In some embodiments a substrate processing system is provided. The substrate processing system may include an equipment front end module (EFEM) coupled to a vacuum-based mainframe, the EFEM having multiple interface openings. A batch degas chamber may be attached to the EFEM at an interface opening of the multiple interface openings. The batch degas chamber may include a housing that is sealed to the interface opening of the EFEM. A cassette may be located within the housing and configured to hold multiple substrates. A reactor chamber may be attached to the housing into which the cassette is insertable, the reactor chamber to perform an active degas process on the multiple substrates. The active degas process removes moisture and contaminants from surfaces of the multiple substrates. An exhaust line may be attached to the reactor chamber to provide an exit for the moisture and contaminants. In one embodiment, the EFEM is an inert EFEM.

In some embodiments, a method of processing substrates is provided. The method may include transferring multiple substrates from a front end opening pod (FOUP) to a cassette of a batch degas chamber, which is one of attached to an equipment front end module (EFEM) or positioned between the EFEM and a vacuum-based mainframe of a substrate processing system. The method may further include lifting a cassette hoist, which includes the cassette of the batch degas chamber, from a housing into a reactor chamber of the batch degas chamber. The method may further include performing, by the reactor chamber, an active degas process on the multiple substrates, wherein the active degas process removes moisture and contaminants from surfaces of the multiple substrates to generate degassed substrates. The method may further include venting, from the reactor chamber through an exhaust line, the moisture and contaminants. The method may further include lowering the cassette hoist with the cassette back into the housing of the degas chamber.

In some embodiments, batch degas chamber is provided. A housing that is sealable to both an interface opening of an equipment front end module (EFEM) and a facet on a vacuum-based mainframe of a substrate processing system. The batch degas chamber may further include a reactor chamber, attached to the housing, into which a cassette is insertable. The cassette is to hold multiple substrates, and the reactor chamber is to perform an active degas process on the multiple substrates. The active degas process removes moisture and contaminants from surfaces of the multiple substrates. The batch degas chamber may further include a cassette hoist positioned within the housing and adapted to move the cassette from the housing into the reactor chamber for processing and return the cassette to the housing after processing. The batch degas chamber may further exhaust line attached to the reactor chamber to provide an exit for the moisture and contaminants.

Numerous other aspects and features are provided in accordance with these and other embodiments of the disclosure. Other features and aspects of embodiments of the disclosure will become more fully apparent from the following detailed description, the claims, and the accompanying drawings.

### BRIEF DESCRIPTION OF THE DRAWINGS

The drawings, described below, are for illustrative purposes only and are not necessarily drawn to scale. The drawings are not intended to limit the scope of the disclosure in any way.

FIG. 1 illustrates a schematic top view of an substrate processing system having an EFEM including a batch degas chamber coupled to a side wall of an EFEM body according to an embodiment.

FIG. 2 illustrates a top plan view of an alternate embodiment of a substrate processing system in which a first batch degas chamber is coupled to the EFEM and a second batch degas chamber is attached to a facet of the mainframe.

FIG. 3A illustrates a front perspective view of the batch degas chamber according to various embodiments.

FIG. 3B illustrates a cross-section view of the cassette within the reactor chamber of the batch degas chamber according to various embodiments.

FIGS. 4A-4B are flowcharts depicting a method of employing the batch degas chamber within the substrate processing system according to various embodiments.

### DETAILED DESCRIPTION

In various embodiments, the present disclosure describes a substrate processing system that achieves lower levels of contamination, higher levels of vacuum, and better productivity in order to meet tolerances and output yields for deposition processes as compared to existing substrate processing systems. These outcomes are difficult to achieve when substrates are passed through an atmospheric factory interface (FI) and degas is performed on contaminated substrates at a degas chamber attached to a facet of a buffer chamber of the vacuum-based mainframe. Pressure in the buffer chamber rises significantly when passing the contaminated substrates between a load lock and the degas chamber in anticipation of performing degas. This buffer pressure recovers slightly as the substrates are degassed, but rises again due to residual contamination when the degas chamber is opened and the substrates are removed from the degas chamber. The higher pressure causes significant delays because the buffer chamber waits until the pressure reaches an acceptable deposition transfer pressure to transfer the substrates into a deposition chamber attached to the buffer chamber or a transfer chamber. The residual contamination can also cause defects on the substrate surfaces during processing.

In order resolve these and other deficiencies, the present disclosure describes embodiments in which a batch degas chamber is attached at an equipment front end module (EFEM), which is also referred to as a factory interface (FI). In some embodiments, the batch degas chamber performs an active degas process on multiple substrates (e.g., between 25 and 75 substrates) in order to remove moisture and contaminants from surfaces of the multiple substrates. The active degas process may be, for example, at least one of a plasma-based process or a heated inert gas process. Once degassed, an FI robot may transfer the degassed substrates from the degas chamber, through the FI, to a load lock before it is transferred on to a processing chamber such as a deposition chamber (e.g., via a vacuum robot in a transfer chamber).

In additional or alternative embodiments, in order to protect the substrates from contamination/corrosion while in transit through the EFEM, the environment within the EFEM may be controlled as inert. The EFEM can be controlled, e.g., by injecting a suitable amount of a non-reactive or inert gas (e.g., N₂) therein to displace oxygen and to reduce moisture levels. This inert EFEM that includes an inert environment provides for protection of the degassed substrates from further contaminants or moisture. In embodiments, the EFEM includes sensors for detecting moisture, pressure, temperature and/or oxygen level in the EFEM. The amount of inert gas that is flowed into the EFEM may be adjusted based on the detected moisture, pressure, temperature and/or oxygen level by controlling one or more valve. Additionally, the EFEM may include exhaust piping. The exhaust piping may include filters for moisture, particles, etc. The exhaust piping may include a recirculation piping that the connects back to an inlet piping through which an inert gas supply delivers inert gas into the EFEM. Inert gas exhausted from the EFEM via the exhaust piping may be filtered and recirculated back into the EFEM.

In the described embodiments, the FI robot in the EFEM transfers substrates from one or more substrate carriers that are docked to a load port on a front wall thereof (e.g., docked to a load port configured on a front wall of the EFEM body). An end effector of an FI robot located in an EFEM chamber formed at least in part by an EFEM body delivers the substrates to the degas chamber for degassing, as will be explained in more detail. Once degassed, the FI robot transfers the degassed substrates to one or more load locks for retrieval by a robot within a buffer chamber or within a transfer chamber. The one or more load locks may be coupled on another surface of the EFEM (e.g., a rear surface thereof) for transfer into a mainframe containing a transfer chamber, a buffer chamber, and/or a pass-through chamber. The transfer chamber may be connected to multiple processing chambers.

In this way, the degassed substrates are passed through the load lock and to one or more processing chambers for processing without further degassing within a degas chamber attached to the vacuum-based mainframe (e.g., without a degas chamber coupled to a transfer chamber or buffer chamber). This order of process, which begins with degas at the factory interface, may involve a number of benefits, including maintaining the pressure (e.g., a vacuum) within the buffer chamber and/or transfer chamber of the mainframe. This is because there is no need to evacuate gasses carrying contaminants within the mainframe. There is also more efficient movement of the substrates into the transfer chamber of the mainframe in skipping the degassing step between transfer into the buffer chamber or transfer chamber and transfer into a processing chamber. Additionally, the transfer of substrates is made more efficient by maintaining a more constant pressure level within the buffer chamber and/or transfer chamber, which mitigates any wait time associated with adjusting pressure within the chambers.

Further, conventionally degas chambers process a single substrate and are coupled to a buffer chamber and/or a transfer chamber of a mainframe, using facets of the mainframe. In embodiments described herein, by way of further advantage, the facets on the mainframe to which the degas chambers were previously attached are freed for other uses, including but not limited to, another deposition chamber such as plasma wafer deposition (PVD) or chemical wafer deposition (CVD) chamber(s). Additional advantages include prevention of cross-contamination between chambers (e.g., transfer chambers, processing chambers and/or buffer chambers) of and/or connected to the mainframe and reduces the load on de-contamination processes within the mainframe between the processing chambers, buffer chamber, pass-through chambers and/or transfer chambers.

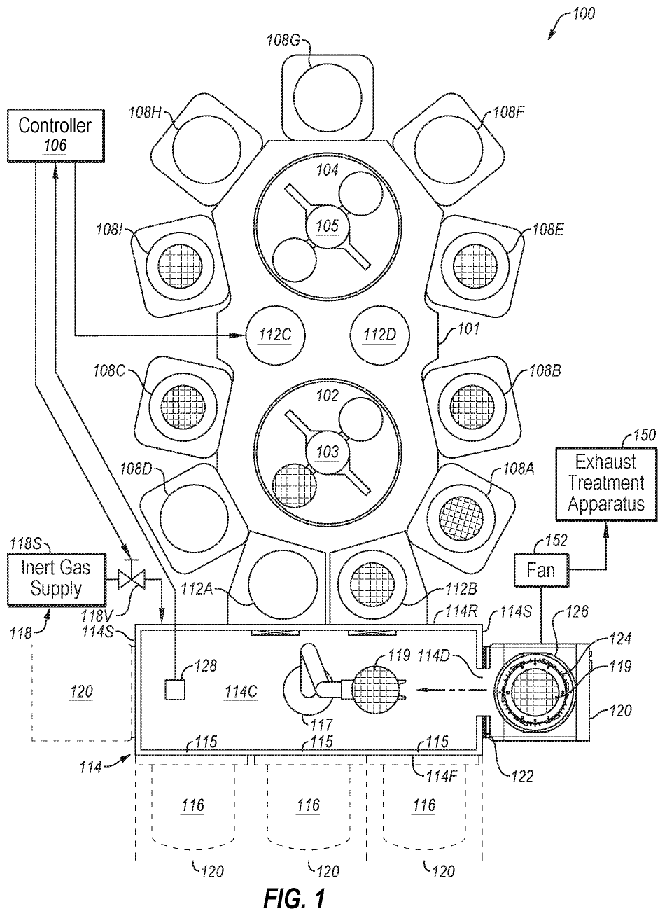

FIG. 1 illustrates a schematic top view of a substrate processing system 100 having an EFEM 114 (also referred to herein as a factory interface (FI)) including a batch degas chamber 120 coupled to a side wall of an EFEM body according to an embodiment. The substrate processing system 100 may include a mainframe 101 (e.g., a vacuum-based mainframe) having mainframe walls defining a buffer chamber 102 and a transfer chamber 104. The buffer chamber 102 may be a type of transfer chamber in embodiments. A buffer robot 103 may be at least partially housed within the buffer chamber 102. The buffer robot 103 may be configured to place and extract substrates to and from various destinations via operations of robot arms of the buffer robot 103. A transfer robot 105 may be at least partially housed within the transfer chamber 104. The transfer robot 105 may be configured to place and extract substrates to and from various destinations via operation of robot arms of the transfer robot 105. Substrates as used herein shall mean articles used to make electronic devices or circuit components, such as semiconductor wafers, silicon-containing wafers, patterned or un-patterned wafers, glass plates, or the like.

In disclosed embodiments, the buffer chamber 102 is coupled to the transfer chamber 104 via one or more (e.g., two) pass-through chambers 112C, 112D. In embodiments, the pass-through chambers 112C, 112D are similar to load lock chambers 112A, 112B. For example, the pass-through chambers 112C, 112D may include stations for buffer robot 103 and/or transfer robot 105 to pick up and place substrates. The pass-through chambers 112C, 112D may or may not include slit valves that enable the pass-through chambers 112C, 112D to be sealed off from transfer chamber 104 and/or buffer chamber 102. In embodiments, the pass-through chambers 112C, 112D are used as cooling stations.

The motion of the various robot arm components of the buffer robot 103 and the transfer robot 105 may be controlled by suitable commands to a drive assembly (not shown) containing a plurality of drive motors commanded from a controller 106. Signals from the controller 106 may cause motion of the various robot arms of the buffer robot 103 and the transfer robot 105. Suitable feedback mechanisms may be provided for one or more of the robot arms by various sensors, such as position encoders, and the like.

The controller 106 may control the transfer robot 105, the buffer robot 103, a FI robot 117, the batch degas chamber 120, and/or further the operation of the substrate processing system. The controller 106 may control the processing and transferring of substrates 119 in and through the substrate processing system. The controller 106 may be, e.g., a computer and/or may include a microprocessor or other suitable CPU (central processing unit), a memory for storing software routines that control electronic device manufacturing system, input/output peripherals, and support circuits such as, e.g., power supplies, clock circuits, a cache, and/or the like. The controller 106 may be programmed to, e.g., process one or more substrates sequentially through each of the process chambers attached to mainframe 101 and/or through batch degas chamber 120. In other embodiments, the controller 106 may be programmed to process a substrate in any order through the process chambers and/or batch degas chamber 120. In still other embodiments, controller 106 may be programmed to skip and/or repeat processing of one or more substrates in one or more process chambers and/or the batch degas chamber 120. The controller 106 may alternatively be programmed to process one or more substrates in the substrate processing system in any suitable manner.

The transfer robot 105 and buffer robot 103 may each include one or more robot arms rotatable about a shoulder axis, which may be approximately centrally located in the transfer chamber and buffer chamber, respectively. The transfer robot 105 and buffer robot 103 may each include a base (not shown) that is configured to be attached to a chamber wall (e.g., a chamber floor) forming a lower portion of the transfer chamber 104 and buffer chamber 102, respectively. However, the buffer robot 103 and/or the transfer robot 105 may be attached to a ceiling in some embodiments. Other types of process chamber orientations such as radially-oriented process chambers, as well as other types of transfer robots, such as selective compliance articulating robot arm (SCARA) robots may be used. As shown, a single processing chamber is coupled to each facet. However, in some embodiments multiple processing chambers couple to a single facet.

Each of the buffer chamber 102 and the transfer chamber 104 in the depicted embodiment may be generally square, rectangular, hexagonal, octagonal, or circular in shape and may include a plurality of facets. The buffer robot 103 and the transfer robot 105 may be adept at transferring and/or retracting substrates 119 from and to process or other chambers accessible by the transfer robot 103.

In the illustrated embodiment, the mainframe 101 includes the buffer chamber 102 and the transfer chamber 104, each of a radial design with eight facets. The buffer chamber 102 and transfer chamber 104 are connected together by two of their respective facets. In other embodiments, the mainframe may have other configurations. For example, the transfer chamber 104 and buffer chamber 102 may have other configurations with a larger number or a smaller number of facets. The facets may all have the same size (e.g., same width and/or length), or different facets may have different sizes. Additionally, the buffer chamber 102 may have a different number of facets from the transfer chamber 104. In one embodiment, the mainframe 101 includes a single transfer chamber coupled to load lock chambers 112A, 112B, and omits the buffer chamber 104 and pass-through chambers 112C, 112D. The single transfer chamber may be a radial transfer chamber with five, six, seven, eight or more facets. Alternatively, the single transfer chamber may include four facets, and may have a square or rectangular shape.

The destinations for the buffer robot 103 may be one or more processing chambers, such as a first processing chamber 108A, a second processing chamber 108B, a third processing chamber 108C, and a fourth processing chamber 108D. Additionally, the buffer robot 103 may place substrates in and retrieve substrates from pass-through chambers 112C, 112D. In a conventional configuration that includes degas chambers, the first processing chamber 108A and the fourth processing chamber 108D may be degas chambers. However, in disclosed embodiments, processing chambers are instead connected to those facets that would ordinarily couple to degas chambers due to the batch degas chamber 120 being positioned at the factory interface. In some embodiments, an adapter is positioned between the facets and the processing chambers 108A and 108D to enable the buffer chamber 102 to interface with a full-sized processing chamber. In this configuration, the substrate processing system 100 may include an increased number of processing chambers, and thus may perform more processing steps as compared to substrate processing systems that use conventional degas chambers that connect to batch chambers and/or transfer chambers.

In order for substrates to be processed in one more additional processing chambers, such as a fifth processing chamber 108E, a sixth processing chamber 108F, a seventh processing chamber 108G, an eighth processing chamber 108H, and a ninth processing chamber 108I, the buffer robot 103 may place the substrates in the pass-through chambers 112C, 112D. Transfer robot 105 may then retrieve the substrates from the pass-through chambers 112C, 112D, and place the substrates in any of fifth processing chamber 108E, sixth processing chamber 108F, seventh processing chamber 108G, eighth processing chamber 108H, and/or ninth processing chamber 108I.

The substrate processing system 100 may further include a first load lock chamber 112A and a second load lock chamber 112B, although additional load lock chambers are envisioned. The load lock chambers 112A, 112B may be single wafer load locks (SWLL) chambers, multi-wafer chambers, batch load lock chambers, or combinations thereof. For example, certain load locks, such as the first load lock 112A, may be used for flow of substrates 119 into the buffer chamber 102, while other load lock chambers, such as the second load lock chamber 112B, may be used for moving substrates out of buffer chamber 102. Similarly, the past-through chamber 112C may be used for flow of substrates 119 into the transfer chamber 104, while pass-through chamber 112D may be used for moving substrates out of the transfer chamber 104 and back to buffer chamber 102.

The various process chambers 108A-108I may be configured and operable to carry out any suitable process of the substrates 119, such as plasma vapor deposition (PVD) or chemical vapor deposition (CVD), etch, annealing, pre-clean, metal or metal oxide removal, or the like. Other deposition, removal, or cleaning processes may be carried out on substrates 119 contained therein.

The substrates 119 may be received into the buffer chamber 102 from an equipment front end module (EFEM) 114, and also exit the buffer chamber 102, to the EFEM 114, through the first and second load lock chambers 112A and 112B that are coupled to a surface (e.g., a rear wall) of the EFEM 114. The EFEM 114 may be any enclosure having an equipment front end module body including chamber walls (such as front wall 114F, rear wall 114R, side walls 114S, and upper (ceiling) and lower (floor) walls (not labeled), for example) forming an EFEM chamber 114C. One of the side walls 114S may include an interface opening 114D through which to gain access to the EFEM chamber 114C.

In various embodiments, a batch degas chamber 120 is attached to the EFEM 114 (e.g., to one of the side walls 114S) at the interface opening 114D. The batch degas chamber 120 may alternatively be positioned between the EFEM 114 and the vacuum-based mainframe, e.g., the mainframe 101. In such an embodiment, the batch degas chamber 120 may also be configured to perform the functions of a load lock chamber. For example, the batch degas chamber may include a first slit valve assembly between the batch degas chamber and the EFEM 114, and may include a second slit valve assembly between the batch degas chamber and the mainframe 101. A corresponding interface opening of the batch degas chamber 120 may include a seal 122 in order to, in some embodiments, allow a vacuum seal to form between the batch degas chamber 120 and the EFEM 114. The seal 122 may be any suitable seal, such as an O-ring seal, a rectangular seal or gasket seal, a bulb seal, and the like. A material of the seal 122 may be propylene diene monomer, a fluoroelastomer, or the like.

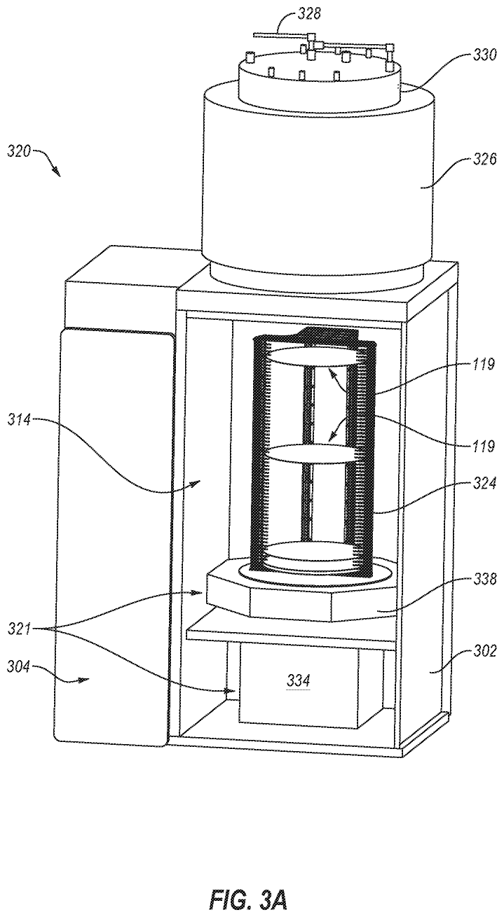

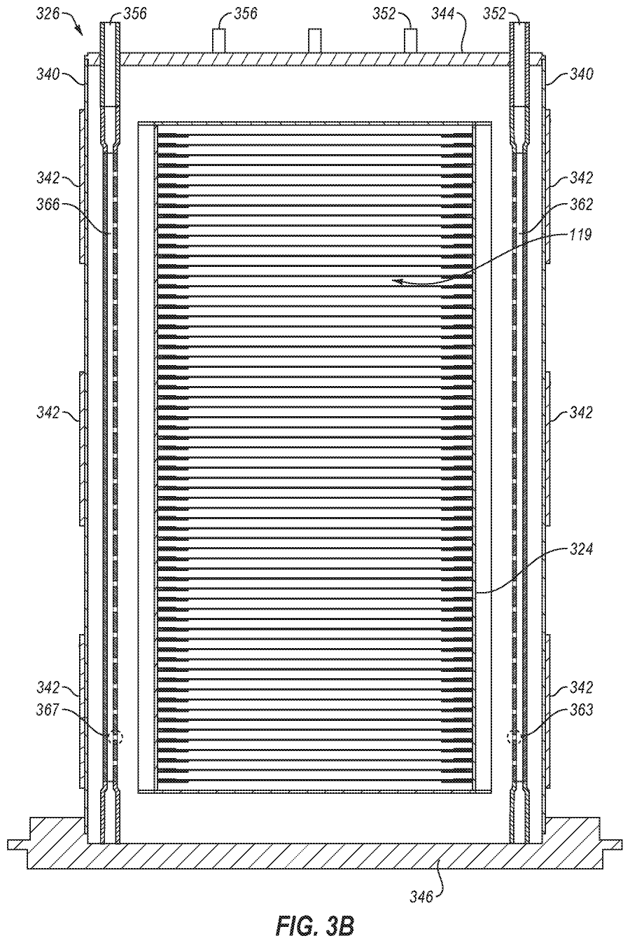

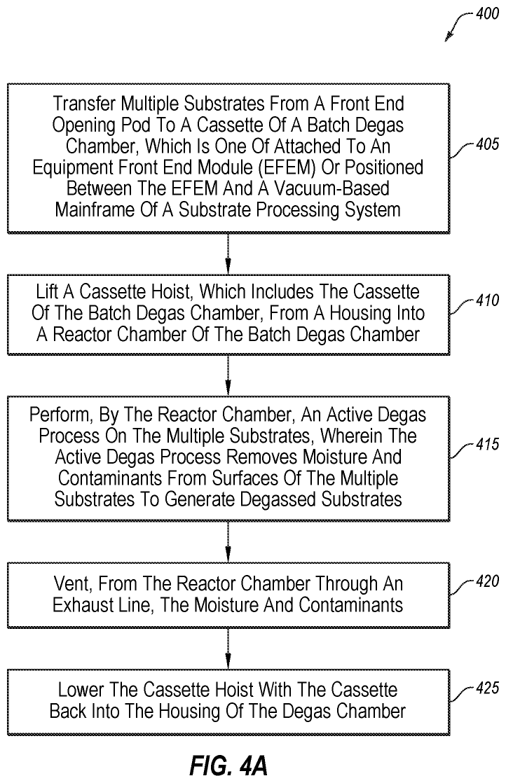

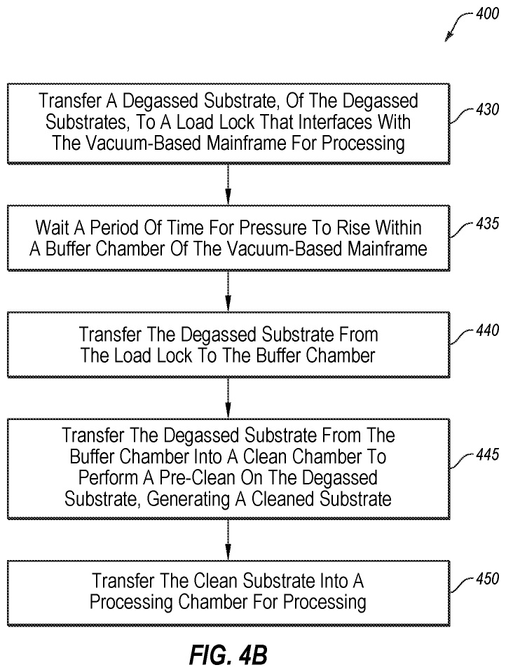

In various embodiments, the batch degas chamber 120 further includes a cassette 124 that may hold multiple substrates 119 (e.g., between up to 25 and up to 75 substrates in embodiments) and a reactor chamber 126 in which the cassette 124 is insertable. The reactor chamber 126 may be separately sealed off from the EFEM 114 environment and the degas chamber housing (as will be illustrated) for degassing the substrates 119, e.g., using plasma-based degassing or a heated inert gas for degassing. The batch degas chamber 120 may further include an exhaust treatment apparatus 150 and a fan 152 to pull and exhaust moisture and contaminants out of the batch degas chamber 120. The batch degas chamber 120 will be discussed in detail with relation to FIGS. 3A-3B and FIGS. 4A-4B.

In additional or alternative embodiments, one or more load ports 115 (e.g., additional interface openings) are provided on surfaces (e.g., front wall 114F) of the EFEM body 114B and may be configured to receive one or more substrate carriers 116 (e.g., FOUPs) thereat. Three substrate carriers 116 are shown, but more or less numbers of substrate carriers 116 may be docked with the EFEM 114. In an alternative embodiment, the batch degas chamber 120 is attached at one of these FOUP positions or at the opposite side from the illustrated batch degas chamber 120, all of which are illustrated in dashed lines.

The EFEM 114 may further include a suitable load/unload robot 117 (e.g., FI robot) within the EFEM chamber 114C thereof. The load/unload robot 117 may include an end effector and may be configured and operational to, once a door of a substrate carrier 116 is opened, such as by a door opener mechanism (not shown), extract the substrates 119 from the substrate carrier 116 and feed the substrates 119 into the cassette 124 of the batch degas carrier 120. The load/unload robot 117 may further be configured and operational to, once the cassette 124 lowers out of the reactor chamber 126 having been degassed, to extract the substrates 119 from the cassette 124, through the EFEM chamber 114C, and into one or more of the first and second load lock chambers 112A, 112B.

Further, the load/unload robot 117 may be configured and operational to extract substrates 119 from one or both of the first and second load lock chambers 112A, 112B and feed the substrates 119 into one or more of the substrate carriers 116. In some embodiments, a side storage pod (SSP) is connected to the EFEM 114, and processed substrates may be placed in the SSP after having been processed, e.g., after processing of the substrates 119 in one or more of the process chambers 108A-108I.

With additional reference to FIG. 1, the EFEM chamber 114C may further include an environmental control system 118 providing an environmentally-controlled atmosphere to the EFEM chamber 114C. In particular, the environmental control system 118 is coupled to the EFEM 114 and is operational to monitor and/or control environmental conditions within the EFEM chamber 114C. In some embodiments, and at certain times, the EFEM chamber 114C may receive a non-reactive (e.g., inert) gas therein, such as during degassing of the substrates 119. The non-reactive gas may be an inert gas such as Argon (Ar), Nitrogen (N₂), helium (He), or the like and may be provided from an inert gas supply 118S. Optionally or additionally, the insert gas supply 118S may include clean dry air with less than 5% relative humidity (RH) at room temperature (RT), for example.

In embodiments, the EFEM 114 includes one or more sensor 128 for detecting moisture, pressure, temperature and/or oxygen level in the EFEM 114. The amount of inert gas that is flowed into the EFEM 114 by the environmental control system 118 may be adjusted based on the detected moisture, pressure, temperature and/or oxygen level by controlling one or more valve. Additionally, the EFEM 114 may include exhaust piping (not shown). The exhaust piping may include filters for moisture, particles, etc. The exhaust piping may include recirculation piping that the connects back to an inlet piping through which an inert gas supply 118S delivers inert gas into the EFEM 114. Inert gas exhausted from the EFEM 114 via the exhaust piping may be filtered and recirculated back into the EFEM 114.

The inert gas supply 118S may be coupled through a control valve 118V to an upper plenum of the EFEM 114. In this manner, a flow of the non-reactive gas (or purge gas) may flow from the upper plenum to the EFEM chamber 114C through the one or more filters, which may be a chemical filter, a particle filter, or both. In one or more embodiments, the non-reactive gas also flows through the batch degas chamber 120, as will be discussed in detail, so that substrates 119 stored therein are exposed to a non-reactive environment. In some embodiments, the non-reactive (or inert) gas performs degassing of the substrates 119.

In some embodiments, if the batch degas chamber 120 is attached to an atmospheric EFEM and thus the EFEM 114 is not inert and/or does not contain an environmentally-controlled atmosphere as discussed above, the substrates may first be sent through a pre-clean within a clean chamber, e.g., one of processing chambers 108A-108D before further processing. In some embodiments, this pre-clean may be performed in addition to processing of the substrate by the batch degas chamber 120. The pre-clean performed with the clean chamber may be one of Anneal Pre-Control (APC) or Plasma-Reactive Pre-Clean (RPC). The APC pre-clean may use chemical and temperature to perform a sublimation process and the RPC may be an RF plasma clean process. The pre-clean performed in this situation is a simple, quick step compared with a full degas of the wafers. Accordingly, even if the batch degas chamber 120 is attached to an atmospheric EFEM and a pre-clean is performed before sending the substrates 119 on to be deposition processed, there is a process efficiency gain, as well as a reduction in pressure variations and risks of cross-contamination within the chambers of the mainframe 101.

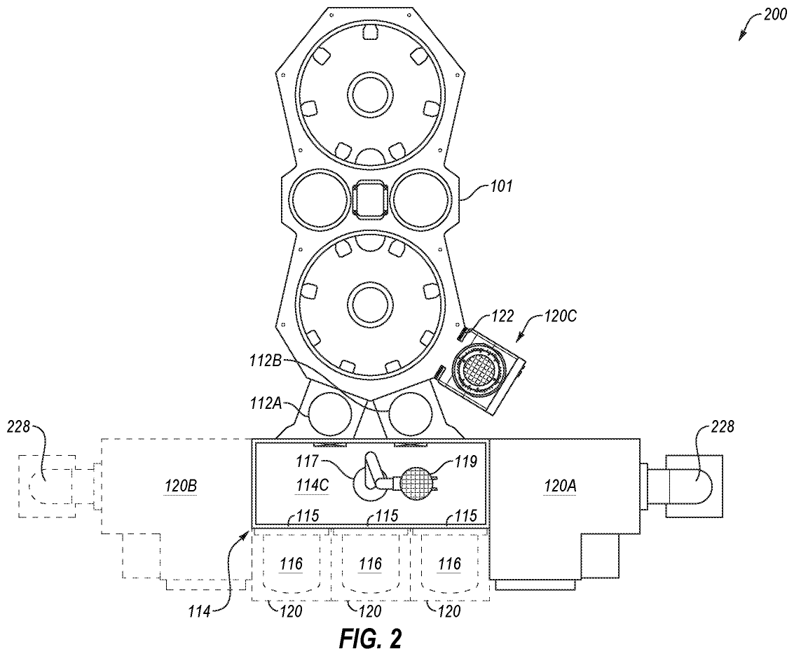

FIG. 2 illustrates a top plan view of an alternate embodiment of a substrate processing system 200 in which a first batch degas chamber 120A is coupled to the EFEM 114 and a second batch degas chamber 120C is attached to a facet of the mainframe 101. For simplicity, the processing chambers and some robots are not illustrated. In one embodiment, the first batch degas chamber 120A is attached to the right side of the EFEM 114, as illustrated. In an alternative embodiment, a different batch degas chamber 120B is attached to the left side of the factory interface, as illustrated in dashes. As discussed, the mainframe 101 may create a vacuum environment in which to transfer and process the substrates 119. The batch degas chamber 120A or 120B and batch degas chamber 120C may be of a same or similar design, or may be of different designs from one another. For example, in one embodiment, the batch degas chamber 120C has a compact configuration and batch degas chamber 120A has a non-compact configuration.

In other embodiments, no batch degas chamber is coupled to the EFEM 114, and the batch degas chamber 120C as described in embodiments herein is coupled to a facet of the mainframe 101. In various embodiments, the seal 122 is positioned between a housing of the batch degas chamber 120C and an interface opening of the facet of the mainframe 101 in embodiments. The seal 122 may allow the vacuum environment to also exist within the batch degas chamber 120C, although the cassette 124 may also form a seal with the reactor chamber 126 as will be explained in more detail. In an embodiment, a port and/or slit valve assembly separates the batch degas chamber 120C from the mainframe 101.

FIG. 2 also illustrates a top view of the batch degas chamber 120A attached to the EFEM 114, and further illustrates an exhaust pipe 228 through which the batch degas chamber 120A may expel moisture and contaminants that are byproducts of the degas process. The exhaust pipe 228 may be attached to reactor 126. In embodiments of a compact configuration of the batch degas chamber, as shown for batch degas chamber 120C, the exhaust pipe may be integral to a frame or body of the batch degas chamber 120C.

FIG. 3A illustrates a front perspective view of the batch degas chamber 320 according to various embodiments. According to various embodiments, the batch degas chamber 320 includes, but is not limited to, a housing 302, alternating current (AC) controls 304, an interface opening 314, a cassette hoist 321, a cassette 324, a reactor chamber 326, an exhaust line 328, and a gas and exhaust access lid 330. In embodiments, the cassette hoist 321 includes a lift 334 (e.g., a mechanical lift, a magnetic lift, a pneumatic lift, etc.) and a reactor door 338, to which the cassette 324 is attached. The interface opening 314 of the housing 302 may be sealable to both an interface opening of the EFEM 114 (FIGS. 1-2) and a facet (FIG. 2) on the vacuum-based mainframe of the substrate processing system 100. As discussed, the seal 122 may be provided in order to create a vacuum environment within the batch degas chamber 320. In embodiments, a slit valve assembly couples to the interface opening 314. The slit valve assembly may include an opening that is adapted to permit a horizontally-oriented substrate to pass therethrough. The slit valve assembly may include a gate and an actuator to open and close the gate. Alternatively, the batch degas chamber 320 does not include a slit valve assembly.

The reactor chamber 326 may be attached to the housing 302. The cassette 324 may be insertable into the reactor chamber 326 and adapted to hold multiple substrates 119. The cassette 324 may be a replaceable part of the batch degas chamber 320. The cassette 324, illustrated in more detail in FIG. 3B, may be adapted to hold a number of substrates 119, such as between 25 and 75 substrates 119, between 20 and 60 substrates, or the like.

As discussed, the cassette hoist 321 may include a lift 334 and a reactor door 338, to which the cassette 324 is attached. In these embodiments, the lift 334 may be attached to the bottom of the reactor door 338. The lift may be a mechanical lift such as. Alternatively, the lift may be a pneumatic lift (e.g., may include or be a pneumatic actuator) or an electromagnetic lift or other type of lift mechanism. The lift 334 may lift the cassette hoist 321, carrying the cassette 324, into and out of the reactor chamber 326. Additionally, the lift 334 may raise or lower the cassette 324 to a height that is reachable by a robot arm. For example, some robot arms have limited or no vertical motion. For such embodiments, a robot arm may position a substrate into a slot of the cassette 324, and the lift 334 may raise the cassette 324 to lift the substrate off of an end effector of the robot arm and onto a finger or support of the slot. Alternatively, the lift 324 may raise or lower the cassette to within a vertical range of motion of a robot arm, and the robot arm may raise and/or lower to remove/place a substrate from/on the cassette 324.

The reactor door 338 may be positioned between the cassette 324 and the lift 334. The reactor door 338 is configured in embodiments to create a seal between the housing 302 and the reactor chamber 326 during processing. In one embodiment, this seal is also a vacuum seal. The lift 334 may raise the reactor door 338 and the cassette 324 held thereon into the reactor chamber 326. The reactor door 338 may include an O-ring or gasket on a top surface of the reactor door 338 around the cassette 324. The lift 334 may press the top surface of the reactor door 338 against a bottom surface of the reactor chamber 326, compressing the gasket or O-ring and sealing off the reactor chamber 326 from an interior of the EFEM or mainframe to which the batch degas chamber 320 is connected.

The reactor chamber 326 may perform an active degas process on the multiple substrates 119. For example, the active degas process removes moisture and contaminants from surfaces of the multiple substrates via one or a combination of a heated inert gas process or a plasma-based process or a heated inert gas process.

The cassette hoist 321 may be positioned within the housing 302 and adapted to move the cassette 324 from the housing 302 into the reactor chamber 326 for processing and return the cassette 324 to the housing 302 after processing, as discussed above.

In various embodiments, the gas and exhaust access lid 330 provides an interface for input gas lines and exhaust gas lines, e.g., at least the exhaust line 328 attached to the reactor chamber 326, to provide an exit for the moisture and contaminants. The exhaust gas lines may be directed to the exhaust pipe 228, 328, or 428, to the outside of the substrate processing system 100.

FIG. 3B illustrates a cross-section view of the cassette 324 within the reactor chamber 326 of the batch degas chamber according to various embodiments. As shown, the cassette 324 includes a scaffolding of supports that each define a slot into which a substrate may be inserted and withdrawn. The supports and slots may be numbered according to a number of substrates that the cassette 324 may hold, and may be regularly spaced apart so that the surfaces of the substrates are exposed to process gases and/or plasma.

The reactor chamber 326 may include, but not be limited to, a wall 340 including multiple zone heaters 342 at intervals along the wall 340. The reactor chamber 326 may include a top heater 344 attached to a top of the wall 340 and a bottom heater 346 attached to a bottom of the wall 340. These zone heaters 342, top heater 344, and bottom heater 346 may provide radiant heat to generate a rapid increase in temperature for performing an active process that removes moisture and contaminants from the surfaces of the substrates 119.

The reactor chamber 326 may further include multiple gas input valves 352 and multiple gas output valves 356 attached to the top heater 344. The reactor chamber 326 may further include multiple gas input lines 362 attached to the multiple gas input valves 352. The multiple gas input valves 352 may force a heated inert gas uniformly through the multiple gas input lines 362. The multiple gas input lines 362 may be between four and eight lines in number, for example, and be oriented vertically across a height of the cassette 324. The multiple gas input lines 362 may include a series of apertures 363 that are numbered and aligned vertically to force heated gas (e.g., inert or non-reactive gas) across each of the multiple substrates 119 in the cassette 324. The gas from the multiple input gas lines 362 may also be heated (e.g., hot flowing inert gas), providing a conductive heat that is in addition to the heat created by the multiple zone heaters 342, the top heater 344, and the bottom heater 346.

The temperature range of the environment inside of the reactor chamber 326 due to the radiant heat and the conductive heat may range between 80 and 450° C., for example. Heat ramp up may be about 5-7° C. per minute at 150° C.

The exposure of the substrates to this heated inert gas flow may prevent or reduce exposure to contaminants or other unwanted conditions (e.g., high humidity levels) and may, when a sufficient flow velocity V is present, cause the degassing of certain unwanted chemical components from the surface of the substrates 119. For example, the unwanted chemical components may be one or more of a bromine-containing component, a chlorine-containing component, fluorine-containing component, and the like. These unwanted chemical components may be disassociated and removed from the surface of the substrates 119 as a result of a suitable flow velocity V of purge gas flow and/or a suitable level of temperature within the reactor chamber 326. Too small of velocity V or temperature may not effectively disassociate the unwanted chemical components. If the flow velocity V is too large then large pressures, high operational cost, and uneven or non-laminar flow through the batch degas chamber 326 may result.

The reactor chamber 326 may further include multiple gas output lines 366 coupled to the multiple output valves 356. The multiple gas output lines 366 may be between four and eight in number, for example, and may also be oriented vertically across a height of the cassette 324. The multiple gas output lines 366 may include a series of apertures 367 numbered and aligned vertically to remove the heated gas with moisture and contaminants from each of the multiple substrates 119 out the exhaust line 328 (FIG. 3A) that is attached to the multiple gas output valves 356. In alternative embodiments, the multiple gas input lines 362 may carry plasma that may be applied to the surfaces of the substrates 119 for subsequent removal. The plasma may create a chemical reaction at the surface of the substrates 119 to remove the contaminants from the surfaces thereof.

FIGS. 4A-4B are flowcharts depicting a method 400 of employing the batch degas chamber 120 and 520 within the substrate processing system 100 according to various embodiments. The method 400 may be performed by the batch degas chamber 120 and 520 and the EFEM 114, discussed and illustrated hereinbefore. In some embodiments, the controller 106 controls the batch degas chamber 120, and causes the batch degas chamber 120 to actuate the lift 534, select a batch degas recipe, execute the batch degas recipe, and so forth to control the processing of the substrates.

At operation 405, the method 400 may begin with transferring multiple substrates from a front end opening pod (e.g., FOUP) to a cassette of a batch degas chamber. The batch degas chamber is one of attached to an equipment front end module (EFEM) or positioned between the EFEM and a vacuum-based mainframe of a substrate processing system.

At operation 410, the method 400 may continue with lifting a cassette hoist, which includes the cassette of the batch degas chamber, from a housing into a reactor chamber of the batch degas chamber. A lift mechanism may be actuated to lift the cassette into a reactor chamber and seal a reactor door against the reactor chamber, thereby creating a closed off and sealed environment for the reactor chamber that is distinct from an environment of an EFEM or mainframe to which the batch degas chamber is connected.

At operation 415, the method 400 may continue with performing, by the reactor chamber, an active degas process on the multiple substrates. The active degas process removes moisture and contaminants from surfaces of the multiple substrates to generate degassed substrates. In one embodiment, the active degas process is a heated inert gas process in which the reactor chamber is heated with zone heaters in wall(s) thereof, e.g., in order to create radiant heat, and also in which the reactor chamber forces a purge (or pressurized) inert gas across the substrates. A combination of the heat and velocity of flow of the heated inert gas causes chemical reactions that purge surfaces of the substrates of chemical contaminants and other particulates. In another embodiment, the active degas process is a plasma-based process in which a plasma is deposited on surfaces of the substrates, and then removed via a chemical reaction. Heat may also be applied to facilitate and speed up the chemical reactions that purge surfaces of the substrates of chemical contaminants and other particulates.

At operation 420, the method 400 may continue with venting, from the reactor chamber through an exhaust line, the moisture and contaminants during the active degas process and/or after the active degas process is complete. At operation 425, the method 400 may continue with lowering the cassette hoist with the cassette back into the housing of the degas chamber, where the FI robot 117 may then retrieve the substrates.

With continued reference to FIG. 4B, at operation 430, the method 400 may continue with transferring a degassed substrate, of the degassed substrates, to a load lock chamber that interfaces with the vacuum-based mainframe for processing.

At operation 435, the method 400 may continue with waiting a period of time for pressure to rise within a buffer chamber of the vacuum-based mainframe. This period of time may be a shorter period of time than would be required if the substrates had not been first degassed. At operation 440, the method 400 may continue with transferring the degassed substrate from the load lock chamber to the buffer chamber.

At operation 445, the method 400 may continue with transferring the degassed substrate from the buffer chamber into a clean chamber to perform a pre-clean on the degassed substrate, generating a cleaned substrate. The clean chamber, as discussed, may be one of an APC or RPC based pre-clean chamber.

At operation 450, the method 400 may continue with transferring the clean substrate into a processing chamber for processing. This processing may be plasma vapor deposition (PVD)-based processing, chemical vapor deposition (CVD)-based processing, and the like.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method may be altered so that certain operations may be performed in an inverse order so that certain operations may be performed, at least in part, concurrently with other operations. In another embodiment, instructions or sub-operations of distinct operations may be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A substrate processing system comprising:
an equipment front end module (EFEM) coupled to a vacuum-based mainframe, the EFEM comprising multiple interface openings; and
a batch degas chamber attached to the EFEM at an interface opening of the multiple interface openings, the batch degas chamber comprising:
a housing that is sealed to the interface opening of the EFEM;
a cassette, located within the housing, configured to hold multiple substrates;
a reactor chamber, attached to the housing, into which the cassette is insertable, the reactor chamber to perform an active degas process on the multiple substrates, wherein the active degas process removes moisture and contaminants from surfaces of the multiple substrates; and
an exhaust line attached to the reactor chamber to provide an exit for the moisture and contaminants.

2. The substrate processing system of claim 1, wherein the EFEM is an inert EFEM comprising an inert environment to substrates passing through the EFEM.

3. The substrate processing system of claim 1, wherein the cassette is configured to hold between 25 and 75 substrates.

4. The substrate processing system of claim 1, wherein the batch degas chamber further comprises a cassette hoist comprising:
a reactor door within the housing to which is attached the cassette; and
a lift attached to a bottom of the reactor door, the lift to cause the cassette to move out of the housing and into the reactor chamber, and wherein the reactor door creates a vacuum seal between the reactor chamber and the housing.

5. The substrate processing system of claim 1, wherein the reactor chamber comprises:
a wall comprising multiple zone heaters at intervals along the wall;
a top heater attached to a top of the wall;
a bottom heater attached to a bottom of the wall;
a plurality of gas input lines comprising a series of apertures numbered and aligned to force heated gas across the multiple substrates in the cassette; and
a plurality of gas output lines coupled to the exhaust line, the plurality of gas output lines comprising a series of apertures numbered and aligned to remove the heated gas with moisture and contaminants from the multiple substrates out of the batch degas chamber via the exhaust line.

6. The substrate processing system of claim 1, wherein the active degas process comprises at least one of a plasma-based process or a heated inert gas process.

7. A method comprising:
transferring multiple substrates from a front end opening pod to a cassette of a batch degas chamber, which is one of attached to an equipment front end module (EFEM) or positioned between the EFEM and a vacuum-based mainframe of a substrate processing system;
lifting a cassette hoist, which includes the cassette of the batch degas chamber, from a housing into a reactor chamber of the batch degas chamber;
performing, by the reactor chamber, an active degas process on the multiple substrates, wherein the active degas process removes moisture and contaminants from surfaces of the multiple substrates to generate degassed substrates;
venting, from the reactor chamber through an exhaust line, the moisture and contaminants; and
lowering the cassette hoist with the cassette back into the housing of the degas chamber.

8. The method of claim 7, further comprising transferring a degassed substrate, of the degassed substrates, to a load lock chamber that interfaces with the vacuum-based mainframe for processing.

9. The method of claim 8, further comprising:
waiting a period of time for pressure to rise within a buffer chamber of the vacuum-based mainframe;
transferring the degassed substrate from the load lock chamber to the buffer chamber;
transferring the degassed substrate from the buffer chamber into a clean chamber to perform a pre-clean on the degassed substrate, generating a cleaned substrate; and
transferring the clean substrate into a processing chamber for processing.

10. The method of claim 7, wherein transferring the degassed substrate comprises transferring the degassed substrate through an inert environment of the EFEM.

11. The method of claim 7, wherein performing the active degas process comprises:
creating a seal between the EFEM and the batch degas chamber; and
performing at least one of a plasma-based process or a heated inert gas process on the multiple substrates within the reactor chamber.

12. The method of claim 7, wherein transferring the multiple substrates to the cassette of the batch degas chamber comprises transferring between 25 and 75 substrates to the cassette.

13. A batch degas chamber comprising:
a housing that is sealable to both an interface opening of an equipment front end module (EFEM) and a facet on a vacuum-based mainframe of a substrate processing system;
a reactor chamber, attached to the housing, into which a cassette is insertable, the cassette to hold multiple substrates, and the reactor chamber to perform an active degas process on the multiple substrates, wherein the active degas process removes moisture and contaminants from surfaces of the multiple substrates;
a cassette hoist positioned within the housing and adapted to move the cassette from the housing into the reactor chamber for processing and return the cassette to the housing after processing; and
an exhaust line attached to the reactor chamber to provide an exit for the moisture and contaminants.

14. The batch degas chamber of claim 13, further comprising the cassette, wherein the cassette is configured to hold from between 25 and 75 substrates.

15. The batch degas chamber of claim 13, further comprising:
a second interface opening of the housing that mates to the interface opening of the EFEM; and
a seal attached to a second interface opening, wherein the seal enables a vacuum to be created within the housing and the reactor chamber.

16. The batch degas chamber of claim 13, wherein the cassette hoist comprises:
a reactor door to which is attached the cassette, the reactor door to create a seal between the housing and the reactor chamber during processing; and
a lift attached to a bottom of the reactor door, the lift to lift the cassette into and out of the reactor chamber.

17. The batch degas chamber of claim 13, wherein the active degas process comprises at least one of a plasma-based process or a heated inert gas process.

18. The batch degas chamber of claim 13, wherein the reactor chamber comprises:
a wall comprising multiple zone heaters at intervals along the wall;
a top heater attached to a top of the wall;
a bottom heater attached to a bottom of the wall;
a plurality of gas input lines comprising a series of apertures numbered and aligned to force heated gas across the multiple substrates in the cassette; and
a plurality of gas output lines coupled to the exhaust line, the plurality of gas output lines comprising a series of apertures numbered and aligned to remove the heated gas with moisture and contaminants from the multiple substrates out the exhaust line.

19. The batch degas chamber of claim 18, wherein the heated gas comprises one of an inert gas or clean dry air.

20. The batch degas chamber of claim 18, wherein the plurality of gas input lines and the plurality of gas output lines each comprise between four and eight lines.
